(19) United States
(12) Patent Application Publication
(10) Pub. No.: US 2019/0352770 A1
(43) Pub. Date: Nov. 21, 2019

(54) METHOD FOR ANTI-REFLECTIVE AND SCRATCH- RESISTANT TREATMENT OF SYNTHETIC SAPPHIRE

(71) Applicant: IONICS FRANCE, Hérouville-Saint-Clair (FR)

(72) Inventors: Denis Busardo, Gonneville-Sur-Mer (FR); Frédéric Guernalec, Liffre (FR)

(21) Appl. No.: 16/482,959

(22) PCT Filed: Feb. 2, 2018
(86) PCT No.: PCT/FR2018/050253

§ 371 Date: Aug. 1, 2019

(30) Foreign Application Priority Data
Feb. 3, 2017 (FR) 17 70113

(51) Int. Cl. C23C 14/48; C23C 14/58

(52) U.S. Cl. CPC C23C 14/48; C23C 14/5806

(57) ABSTRACT

Method of antireflection and scratch-resistant treatment of a synthetic sapphire material where the acceleration voltage of the ions is between 5 kV and 1000 kV and is chosen in order to create an implanted layer having a thickness equal to a multiple of 100 nm; the microwave-induced annealing temperatures in the implanted surface are between 800° C. and 2000° C. with annealing times of between 1 and 1000 seconds. Synthetic sapphire materials are thus advantageously obtained where the reflection on the treated face is reduced by at least half while maintaining a hardness of greater than or equal to 8.

### CROSS REFERENCE TO RELATED APPLICATIONS

This application is a U.S. National Phase of International Patent Application No. PCT/FR2018/050253, filed on Feb. 2, 2018, which claims benefit of priority of French Patent Application No. 1770113 filed on Feb. 3, 2017, the respective disclosures of which are each incorporated herein by reference in their entireties.

### BACKGROUND

### Field of the Disclosure

The invention relates to an antireflection scratch-resistant treatment for a synthetic sapphire material, using an ion implantation and a microwave-induced ultrarapid surface annealing; this method targets an antireflection treatment that reduces, at least by half, the reflection of a wave in the visible range while maintaining a hardness on the Mohs scale of greater than or equal to 8. The method of the invention is applied in particular to the surface of a synthetic sapphire watch glass, to synthetic sapphire display screens and any other object where it is desired, on the outer face made of synthetic sapphire, to guarantee very high scratch resistance and good light transmittance in the visible range (located between 380 and 800 nm).

### Brief Description of Related Technology

“Synthetic sapphire” is understood to mean a material that is transparent to visible light. Synthetic sapphire is formed of aluminium oxide (Al₂O₃). From a physical point of view, synthetic sapphire is a very hard crystalline material (hardness equal to 9 on the Mohs scale) belonging to the family of corundums, having a very high refractive index equal to 1.76.

Natural sapphires are formed of crystals of aluminium oxide (Al₂O₃) containing impurities (oxides) in trace amounts that give them their colour (titanium and iron for blue, vanadium for violet, chromium for pink, and iron for yellow and green). The colour is due to the appearance of energy levels within the forbidden band of the corundum, due to the presence of impurities. These levels modify the emission and absorption spectra of the material and therefore its colour.

Natural sapphire may be heat-treated; stones that are too light, too dark or have a lot of inclusions are heated. This method makes it possible to enhance colour and clarity by dissolving the elements present in trace amounts in the stone.

Since the beginning of the 19^{th} century, it has been known how to manufacture, in the laboratory, synthetic sapphires and synthetic rubies, the chemical composition and physical properties of which are the same as those of natural stones. It is however possible to detect these synthetic stones by their generally curved crystallization lines, at least for the oldest productions.

Due to its property of high scratch resistance, synthetic sapphire is used as watch glass or camera lens especially in smartphones. The manufacture of synthetic sapphire is today at the industrial stage.

It is well known that a surface made of synthetic sapphire reflects around 15.5% of the incident light, reducing the reading of a watch, or of a computer or mobile telephone flat screen.

This reflection of the light on a surface made of synthetic sapphire is explained more generally by the Fresnel equations that give, for a light ray passing through a dioptre under an angle of incidence of 90°, the following reflection coefficient (R) and transmission coefficient (T):

R=((n2−n1)/(n2+n1))²; T=4n1*n2/(n2+n1)²

where n1 and n2 are the indices of reflection of the media separated by the dioptre.

It is observed that R+T=1 (conservation of energy)

Obtained with these formulae for air (n1=1) and synthetic sapphire (n2=1.76) are R=0.0758, T=1-R=0.9242 (only 7.6% is reflected whilst 92.4% is transmitted).

For a synthetic sapphire strip formed of two faces, there is a loss which is two times greater, 2×7.6%=15.2%. This high reflection makes it difficult to read the components of a watch (hands, calendar, decorations, etc.) located under the watch glass.

### BRIEF DESCRIPTION OF THE DRAWINGS

FIGS. 1.a and 1.b are schematic illustrations depicting the propagation of an incident wave without and with an antireflection layer.

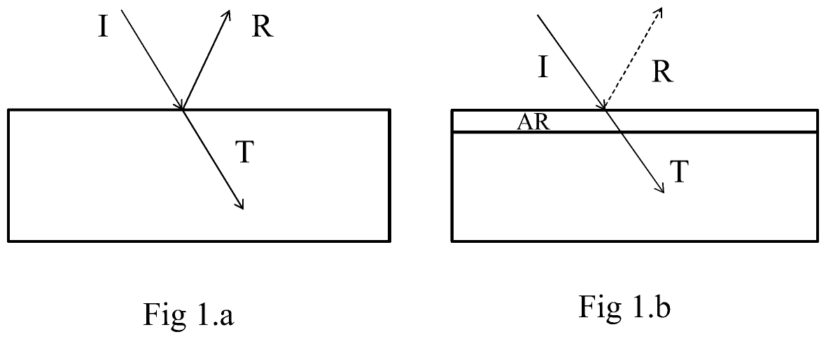

### DETAILED DESCRIPTION

The inventors have developed an antireflection method that consists in implanting, in a surface made of synthetic sapphire, nitrogen or oxygen ions with an energy approximately between 20 and 40 keV (kiloelectron volt) and at doses lying approximately between 5×10¹⁶ ions/cm² and 2×10¹⁷ ions/cm².

These antireflection treatments make it possible to significantly increase the transmittance of a treated face by around 6% (by way of indication, the transmittance of synthetic sapphire for which a single face has been treated goes from 85.5% to a value greater than or equal to 91.5% at 560 nm). This treatment however has one drawback: the hardness of the original synthetic sapphire, estimated at 9 on the Mohs scale, drops to 4-5 Mohs for oxygen and to 7-8 for nitrogen. For applications where it is sought to retain as far as possible a scratch resistance close or even comparable to that of the synthetic sapphire, this is a prohibitive point.

This drop in hardness is associated with an amorphization of the synthetic sapphire in the implantation zone travelled through by the ions. By giving up their energy the ions create, over the passage thereof, defects in the form of vacancies which have the effects of degrading the crystalline structure of the synthetic sapphire and of weakening the surface mechanical properties of the synthetic sapphire. Beyond the implantation zone, which does not exceed approximately 0.5 microns, the hardness characteristics of the synthetic sapphire are found again. The implanted ions located within these 0.5 microns make it possible to create an index gradient that is behind the antireflection properties.

The inventors have carried out conventional annealing operations (using ambient air furnaces) on synthetic sapphire treated by oxygen or nitrogen implantation. The implantation conditions were the following: nitrogen (30 keV (kiloelectron volt), implanted dose 1.5×10¹⁷ ions/cm²); oxygen (30 keV (kiloelectron volt), implanted dose 1.5×10¹⁷ ions/cm²). The furnace annealing conditions for the treated synthetic sapphires were the following: (450, 800, 935 and 1450° C. for 1 hour). Irrespective of the type of ion and the annealing conditions used, maintaining the optical properties (transmittance greater than or equal to 90%) is accompanied by a reduction in the Mohs hardness (less than 7) and the increase in hardness by annealing (Mohs hardness tending towards 8) is accompanied by a steep drop in the transmittance (less than 88% for 560 nm). The furnace annealing technique has proved ineffective for obtaining a scratch-resistant antireflection treatment for synthetic sapphire characterized by a hardness greater than or equal to 8 on the Mohs scale and a transmittance greater than or equal to 90% for a synthetic sapphire treated on only one face (corresponding to a reduction of at least 50% in the reflection).

From all the above, it results that there is a need for an antireflection treatment for a synthetic sapphire material, the scratch resistance properties of which are substantially close or even comparable to that of the original synthetic sapphire, preferably according to methods that can be easily industrialized, so as to be able to offer such materials made of antireflection and scratch-resistant treated synthetic sapphire in a significant amount and at reasonable costs.

The objective of the invention is to offer a antireflection scratch-resistant treatment by ion implantation and microwave annealing that is not very expensive and that makes it possible to treat surfaces that meet the needs of numerous applications. Among these applications mention will be made of: touch screens, watch glasses, lenses of an optical device.

The invention thus proposes an antireflection scratch-resistant treatment for a synthetic sapphire material, characterized by a hardness on the Mohs scale of greater than or equal to 8 and by a reflection reduced by at least 50% for a wavelength of 560 nm, consisting of two steps:

A first step that carries out an ion beam bombardment where:
the dose of ions implanted per unit of surface area is chosen within a range between 10¹⁶ ions/cm² and 10¹⁸ ions/cm² so as to obtain an atomic concentration of ions such that the refractive index n of the implanted layer is approximately equal to (n1*n2)^{1/2} where n1 is the index of the air and n2 is the index of the synthetic sapphire;
the acceleration voltage is chosen within a range between 5 kV and 1000 kV so as to obtain an implanted thickness e equal to p*λ/4*n where e is the implanted thickness corresponding to an implantation zone where the atomic concentration of implanted ions is greater than or equal to 1%, where p is an integer, λ is the incident wavelength and n is the index of the implanted layer.

A second step where the surface annealing is carried out at temperatures between 800° C. and 2000° C. and over two very short times of between 0 and 1000 seconds by exposing the implanted surfaces to ultrarapid surface heating produced by microwaves.

According to one embodiment, the ions of the ion beam are selected from the ions of the elements from the list of “noble” gases, consisting of helium (He), neon (Ne), argon (Ar), krypton (Kr) and xenon (Xe).

According to another embodiment, the ions of the ion beam are selected from the ions of the gases from the list consisting of nitrogen (N₂) and oxygen (O₂).

The choice of the gas ions, of the bombardment conditions with these ions and of the annealing conditions according to the invention makes it possible to advantageously obtain a reduction in the reflection coefficient, an increase in the transmission coefficient and a maintaining of the scratch-resistance properties close or even comparable to that of the synthetic sapphire. These properties are very important for improving the ease of reading a watch or screen in an outside environment by greatly reducing the reflections and by maintaining sufficient scratch resistance characteristics with regard to the mechanical stresses to which these objects may be subjected.

The inventors have been able to observe that the ranges chosen according to the invention of acceleration voltage and of dose of gas ions per unit of surface area make it possible to select experimental conditions where the reduction in the reflections (of at least 50%) is possible owing to an ion bombardment of gas ions and that the implanted layer can be scratch resistant by increasing the surface hardness by microwave-induced ultrarapid surface annealing within the ranges indicated by the invention. This hardness should, after annealing, be greater than or equal to 8 on the Mohs scale.

During a first step, the choice of the dose of gas ions per unit of surface area in the dose range according to the invention may result from a prior calibration step where a sample consisting of the synthetic sapphire material envisaged is bombarded with one of the gas ions for example chosen from He, Ne, Ar, Kr, Xe, N₂, O₂. The bombardment of this synthetic sapphire material may be carried out in various zones of the material with a plurality of doses of gas ions, within the range according to the invention. The transmittance at 560 nm of the treated zones is then measured so as to choose the optimal dose that makes it possible to achieve a maximum transmittance (i.e. a minimum reflection).

A second step consists in regulating the frequency and the power of the microwaves to obtain the shortest possible temperature rises (for example 1 second) on a synthetic sapphire treated under the conditions identified during the first step. Several synthetic sapphires treated under the same conditions as those identified during the first step are then exposed to annealing temperatures, sampled every 200° C. between 800° C. and 2000° C., having a respective value of 800° C., 1000° C., 1200° C., 1400° C., 1600° C., 1800° C. and 2000° C., according to three annealing times of 1, 10 and 100 seconds for each annealing temperature, so as to only retain the annealing conditions for which the Mohs hardness is greater than or equal to 8 and the reflection is reduced by at least 50% for a wavelength of 560 nm.

There is another ultrarapid surface annealing technique that has, unlike the one that uses microwaves, the drawback of not being commercially viable.

Without wishing to be bound by any one scientific theory, it is conceivable that the phenomenon of ultrarapid annealing with microwaves has the effect of annealing the crystalline defects (vacancies) at a speed greater than that needed to diffuse the implanted ions; the surface hardness associated with the reduction in the defects (recrystallisation) is thus increased while degrading the antireflection properties associated with the implanted ions as little as possible.

According to various embodiments, that may be combined:
the dose of gas ions per unit of surface area is greater than or equal to 10¹⁶ ions/cm², for example greater than or equal to 10¹⁷ ions/cm²;
the acceleration voltage of the gas ions is between 20 kV and 40 kV;
the acceleration voltage is chosen in order to obtain an implanted thickness equal to p*100 nm where p is an integer;
the synthetic sapphire material is movable relative to the beam of gas ions at a speed, V_{D}, of between 0.1 mm/s and 1000 mm/s; according to one embodiment, a same zone of the synthetic sapphire material is moved under the beam of gas ions according to a plurality, N, of passes at the speed V_{D};
the device for ultrarapid microwave annealing of the treated synthetic sapphire comprises an RF signal generator, a microwave power amplifier, a microwave heating head located above the treated synthetic sapphire to be annealed, a pyrometer located below the treated synthetic sapphire in order to measure the temperature, a computer-controlled feedback system that makes it possible to regulate the frequency of the RF signal and the microwave power amplifier in order to obtain high and stable heatings over relatively short annealing times that vary from 1 to 1000 seconds. For further details on the technical principles of microwave heating reference may be made to patent published under the number EP 0 076 769 A1.

The present invention also targets a synthetic sapphire part comprising at least one surface with an implanted and microwave-annealed ion according to the method of the invention, according to any one of the embodiments above, where the reflection of an incident wave of 560 nm is reduced at least by half and the hardness of said surface is greater than or equal to 8 on the Mohs scale.

The present invention also targets the use of the treatment method, according to any one of the embodiments above, for treating a solid synthetic sapphire part chosen from the list consisting of a touch screen, a watch glass, a lens of an optical device.

According to exemplary embodiments of the present invention, samples of synthetic sapphire material were the subject of studies, with singly-charged and multicharged nitrogen ions.

These singly-charged and multicharged gas ions were emitted by an ECR source.

The inventors carried out a first series of tests with a beam of singly-charged and multicharged nitrogen ions having an intensity of 1 mA comprising N⁺ and N²⁺ ions; the acceleration voltage is 20 kV; the energy of N⁺ is 20 keV (kiloelectron volt) and that of N²⁺ is 40 keV (kiloelectron volt). The treatment dose is equal to 1.5×10¹⁷ ions/cm². The N⁺ ions constitute approximately 50% of the beam, the N²⁺ ions constitute approximately 50% of the remaining ions.

The sapphire samples are moved relative to the beam with a speed of movement of 80 mm/s and with a lateral advance at each return of 4 mm (10% of the beam diameter which measures 40 mm). In order to achieve the necessary dose, the treatment is carried out in several passes.

The inventors observed that at 560 nm the dose is optimal, the transmittance of the synthetic sapphire treated on a single face goes from 85% to 92%. The Mohs hardness of the treated face is between 7-8.

For the samples treated and microwave-annealed at 1000° C. for 100 s, the inventors observed that the treated synthetic sapphire regains a hardness greater than or equal to 8 and that the transmittance remains greater than or equal to 90% (reflection of the treated face reduced by 70%).

1. A method of antireflection scratch-resistant treatment in the visible range of a synthetic sapphire material, comprising:
bombarding a surface of the synthetic sapphire material with a beam of gas ions to implant gas ions in the surface and form an implanted layer, wherein:
a dose of gas ions implanted per unit of surface area is chosen within a range between 10¹⁶ ions/cm² and 10¹⁸ ions/cm² so as to obtain an atomic concentration of gas ions such that a refractive index n of the implanted layer is approximately equal to (n1*n2)^{1/2} where n1 is the refractive index of the air and n2 is the refractive index of the synthetic sapphire, and
an acceleration voltage is chosen within a range between 5 kV and 1000 kV so as to obtain an implanted thickness e equal to p*λ/4*n where e is the implanted thickness corresponding to an implantation zone where the atomic concentration of implanted gas ions is greater than or equal to 1%, where p is an integer, λ is the incident wavelength and n is the index of the implanted layer; and
annealing the implanted layer by microwave-induced heating to an annealing temperature:
between 800° C. and 2000° C.; for an annealing time between 1 and 1000 seconds.

2. The method according to claim 1, characterized in that the gas ions of the beam of gas ions are selected from ions of elements selected from the group consisting of helium (He), neon (Ne), argon (Ar), krypton (Kr), and xenon (Xe).

3. The method according to claim 1,
characterized in that the gas ions of the beam of gas ions are selected from ions of gases selected from the group consisting of nitrogen (N₂) and oxygen (O₂).

4. The method according to claim 1, characterized in that the acceleration voltage is chosen so as to obtain an implanted thickness equal to p*100 nm where p is an integer.

5. The method according to claim 1, characterized in that the synthetic sapphire material is movable relative to the beam of gas ions at a speed, V_{D}, of between 0.1 mm/s and 1000 mm/s.

6. The method according to claim 5, characterized in that a same zone of the synthetic sapphire material is moved under the beam of gas ions according to a plurality, N, of passes at the speed V_{D}.

7. A synthetic sapphire part comprising at least one surface with an implanted and surface-annealed ion treatment performed by the method of claim 1, characterized in that the reflection of an incident wave of 560 nm is reduced at least by half and that said surface has a Mohs hardness of greater than or equal to 8.

8. The method according to any one of claim 1, wherein the synthetic sapphire material is a solid part selected from the group consisting of a touch screen, a watch glass, and a lens of an optical device.

9. The method of claim 1, wherein the beam of gas ions comprises singly-charged and multi-charged gas ions.
